(19) United States
(12) Patent Application Publication
(10) Pub. No.: US 2006/0147625 A1
(43) Pub. Date: Jul. 6, 2006

(54) Method and device for the cvd coating of workpieces

(76) Inventor: Frank Seidel, Isernhagen H.B. (DE)

Correspondence Address: CROWELL & MORING LLP;INTELLECTUAL PROPERTY GROUP, P.O. BOX 14300, WASHINGTON, DC, 20044-4300, US

(21) Appl. No.: 10/538,953

(22) PCT Filed: Nov. 26, 2003
(86) PCT No.: PCT/DE03/03916

§ 371 Date: Mar. 13, 2006

(30) Foreign Application Priority Data
Dec. 14, 2002 (SE) 102 58 560.1

(51) Int. Cl. C23C 16/00

(52) U.S. Cl. 427/248.1; 118/719; 118/726

(57) ABSTRACT

A method and a device for CVD coating of a workpiece is disclosed. In an embodiment of the method for CVD coating, in particular for aluminizing at least one workpiece, a coating gas which serves to coat the workpiece or each workpiece is created. The workpieces to be coated are arranged in a coating room where coating granules are arranged near the workpieces. The coating room, together with the workpieces to be coated and the coating granules, is heated to the process temperature. After reaching the process temperature, a process gas is introduced onto the coating granules to create a coating gas.

This application claims the priority of International Application No. PCT/DE03/03916, filed Nov. 26, 2003, and German Patent Document No. 102 58 560.1, filed Dec. 14, 2002, the disclosures of which are expressly incorporated by reference herein.

### BACKGROUND AND SUMMARY OF THE INVENTION

This invention relates to a method for CVD coating of workpieces. In addition, the invention relates to a corresponding device.

Numerous methods for coating workpieces are known from the state of the art. So-called CVD (chemical vapor deposition) coating is a coating method based on the chemical reaction of gases. CVD coating is also used in so-called aluminizing, a surface protection method in which aluminum is introduced into the surface of metallic components.

In CVD coating, to ensure optimum coating results, a uniform coating-active atmosphere must be created in a so-called coating room in which the workpieces to be coated are arranged. To ensure a uniform coating-active atmosphere in large coating rooms, also called coating ovens, for all the workpieces to be coated, the workpieces to be coated are arranged in the coating room in state of the art coating boxes according to the state of the art.

The actual coating of the workpieces takes place in these coating boxes. The coating boxes have a small volume in comparison with the actual coating room so that a uniform coating-active atmosphere can be created within the coating boxes. The use of such coating boxes in the coating room is a disadvantage, however, because the coating boxes take up a great deal of room inside the coating room so that the coating room cannot be utilized efficiently. In addition, the coating boxes have a relatively great mass in relation to the workpieces to be coated, resulting in long heating times to achieve a process temperature, i.e., coating temperature, and likewise long recooling times. Therefore, if coating boxes are used, this results in a long coating operation. This also limits the efficiency of the coating method and/or the device for coating. Furthermore, coating boxes are expensive and must be replaced from time to time, which is associated with cost disadvantages.

If coating boxes according to the state of the art are to be eliminated, it has been necessary in the past to use coating rooms having a small volume. With such small coating rooms, it is possible to eliminate the coating boxes, but on the other hand, only a limited number of workpieces to be coated can be arranged inside the coating room. This is also a disadvantage from the standpoint of efficacy.

Against this background, the object of the present invention is to create a novel method for CVD coating and a novel device for CVD coating.

According to this invention, workpieces to be coated are arranged in a coating room, with coating granules arranged in the vicinity of the workpieces to be coated. The coating room together with the workpieces to be coated and together with the coating granules is heated to the process temperature. After reaching the process temperature, a reactive process gas is introduced and passed directly over the coating granules, thereby creating the coating gas. This makes it possible to achieve a uniform and highly coating-active atmosphere in the entire coating room. Coating boxes may be omitted, so that on the one hand the space in the coating room is utilized well while on the other hand a positive dynamic coating process is achieved. There is also a considerable reduction in cost.

According to an advantageous embodiment of this invention, workpieces to be coated in the coating room are positioned in several levels arranged one above the other, with coating granules being arranged in the area of each level directly beneath the workpieces to be coated. The process gas is introduced onto the coating granules in the area of each level. This ensures optimum utilization of the coating room while at the same time ensuring a uniform highly coating-active atmosphere in the entire coating room.

A process pressure is preferably pulsed during the holding time by lowering the process pressure by withdrawing the coating gas and then generating new coating gas. It is possible to produce interior coatings in this way.

### BRIEF DESCRIPTION OF THE DRAWINGS

An exemplary embodiment of this invention is explained in greater detail below on the basis of the drawings although the invention is not limited to this embodiment.

FIG. 1 is a highly-schematic diagram of an inventive device for CVD coating of a workpiece to illustrate the inventive method.

FIG. 2 is a detail of the device according to FIG. 1.

### DETAILED DESCRIPTION OF THE DRAWINGS

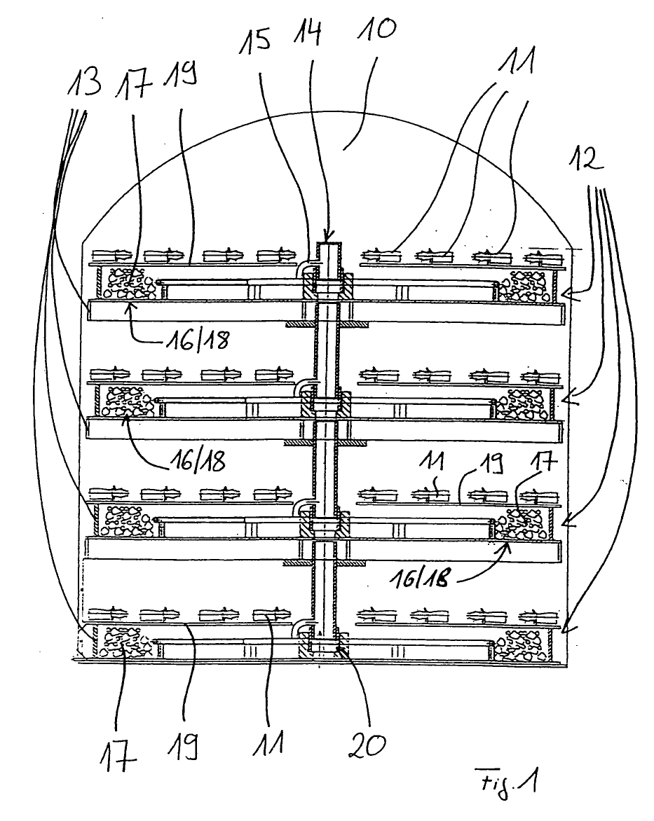

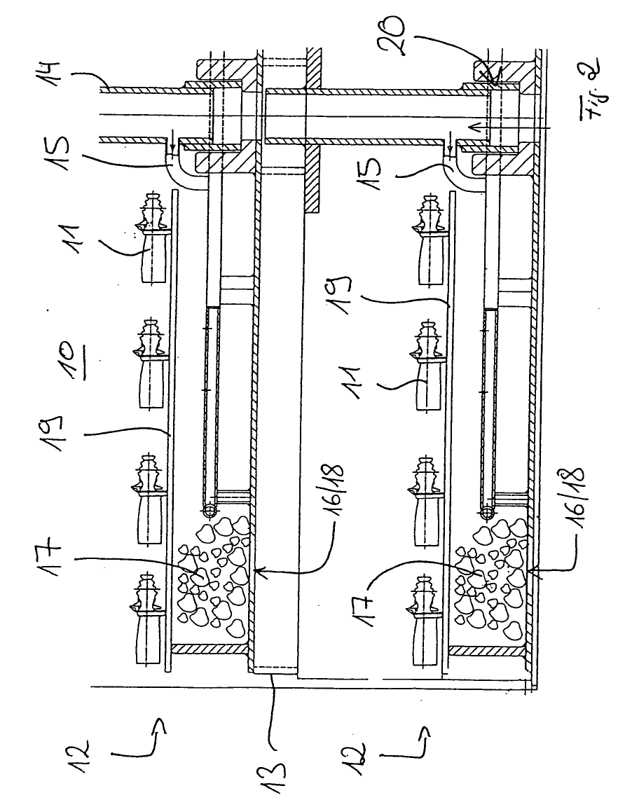

FIG. 1 shows an inventive device for CVD coating of workpieces that are to be coated. FIG. 2 shows an enlarged detail of the inventive device according to FIG. 1.

The inventive device according to FIG. 1 and FIG. 2 is preferably used for aluminizing turbine parts, e.g., compressor blades.

The inventive device according to FIGS. 1 and 2 comprises a coating room 10 which is referred to as the coating oven or the retort oven. Several workpieces 11 to be coated are arranged inside the coating room. The workpieces to be coated are positioned in the coating room 10 in several levels 12 arranged one above the other. According to FIG. 1, the workpieces 11 are positioned in a total of four levels 12 arranged one above the other, with a total of eight workpieces 11 being shown for each level 12.

In the area of each level 12 a supporting frame 13 is positioned, preferably extending over the entire width of the coating room 10. The supporting frame 13 thus extends in the horizontal direction of the coating room 10. Between supporting frames 13 arranged one above the other there extends a pipe 14 in the vertical direction of the coating room 10. In the area of each level 12, the pipe 14 has a branch 15.

Receptacle devices 16 for coating granules 17 are arranged on the supporting frames 13. The receptacle devices 16 have a holding tray 18 for the coating granules 17, whereby the holding tray 18 is bordered at the top by a grating 19. The workpieces 11 to be coated lie on the grating 19 of each receptacle device 16. Accordingly, coating granules 17 are arranged directly beneath the workpieces 11 to be coated in the area of each level 12.

The pipe 14 running vertically serves to guide the process gas. In the exemplary embodiment according to FIG. 1 and FIG. 2, process gas is introduced into a bottom section 20 of the pipe 14 and is moved vertically upward. In the area of the branches 15, some of the process gas moving through the pipe 14 is branched off, i.e., deflected in the direction of the receptacle devices 16. In this way, process gas may go uniformly in the direction of all the receptacle devices 16 arranged in the coating room 10 and therefore can ultimately reach the coating granules 17 situated there. If the process gas reaches the coating granules 17 at a predetermined process temperature, i.e., coating temperature, the coating gas is thereby generated, ultimately forming the coating on the workpieces 11 that are to be coated. The receptacle devices 16 may thus also be referred to as devices for generating the coating gas, i.e., as coating gas generators.

Therefore, for CVD coating of the workpieces 11, the procedure followed with the inventive device is such that the workpieces 11 to be coated are positioned on the gratings 19 of the receptacle devices 16 in the area of the levels 12. In this way the workpieces 11 to be coated are arranged in the coating room. Coating granules are arranged in the coating room 10 in the immediate proximity of the workpieces to be coated, namely beneath the gratings 19. With the help of a heating (not shown), the coating room 10 and thus the workpieces 11 situated in the coating room 10 as well as the coating granules 17 arranged in the coating room 10 are heated to a predetermined process temperature, i.e., coating temperature. After reaching this process temperature, the process gas is introduced through the pipe 14 into the coating room 10. The process gas goes through the branches 15 uniformly in the direction of all levels 12 and thus ultimately uniformly directly onto the coating granules 17 arranged in the area of the levels 12 running one above the other. In this way the coating gas is generated uniformly in the entire coating room 10. A uniform coating-active atmosphere is established in the entire coating room 10.

It thus within the sense of the present invention to first heat the workpieces 11 that are to be coated and the coating granules 17 in the coating room 10 to the process temperature. Only after heating to the process temperature is the process gas conveyed in the direction of the coating granules. A halide gas is used as the coating gas. By using the receptacle devices 16 which are described above and which are filled with coating granules 17, devices for generating the coating gas are thus made available, these devices being situated inside the coating room 10 near the workpieces 11 that are to be coated. The receptacle devices 10 filled with coating granules 17 thus constitute internal coating gas generators. They can easily be installed in the different levels 12 of the coating room 10. Coating boxes which are necessary in large-scale coating rooms according to the state of the art can be omitted entirely here. This yields a positive, dynamic behavior of the inventive method because the heating time and recooling time are reduced by the elimination of the coating boxes. This also yields cost advantages.

It should be pointed out here that heating of the coating room 10 and thus heating of the workpieces 11 that are to be coated as well as the coating granules 17 are performed under a hydrogen atmosphere or an argon atmosphere. As soon as the coating temperature, i.e., the process temperature, has been reached, the halide gas is directed at the coating granules 17. Then during a holding time in the process, the process parameters are kept constant. The actual coating of the workpieces 11 that are to be coated takes place during this holding time. By purging the coating room 10 with hydrogen, the coating process can be terminated.

In the case when the coating room 10 is designed to be suitable for a vacuum, a vacuum is generated in the coating room 10 by pumping out the atmosphere prevailing during heating, preferably after reaching the process temperature, i.e., the coating temperature, and before introduction of the process gas in the form of a halide gas. Only after the vacuum is established is the halide gas introduced into the coating room 10. To do so, a pump mechanism (not shown) is assigned to the inventive device.

Interior coating of the workpieces to be coated can also be achieved with the inventive method. To do so, the coating operation is in the meantime subjected to pressure pulsations during the holding time. The process pressure here is reduced by withdrawing coating gas and/or lowering the coating gas generated in the coating room 10. Then fresh coating gas is generated by again introducing halide gas onto the coating granules 17 until the process pressure has been restored again. The coating gas removed is thus replaced by fresh coating gas.

The inventive method and the inventive device allow a number of advantages to be achieved in comparison with the state of the art.

Due to the elimination of coating boxes, the coating room 10 can be utilized efficiently. The number of workpieces 11 being coated in the coating room 10 can be doubled or even tripled.

In addition, due to the elimination of the coating boxes, the process time of the inventive method is greatly reduced because the heating time and the recooling time are shortened due to the reduced mass in the coating room 10.

In addition, operating costs are reduced due to the elimination of the coating boxes.

Through this invention, a uniform distribution of the coating gas and thus a uniform coating-active atmosphere can be created in the entire coating room 10. A highly efficient CVD coating can now be implemented even in large-scale coating rooms.

Due to the fact that the process gas is directed at the coating granules only after heating of the workpieces 11 and the coating granules 17, the coating process can be controlled accurately.

Use of a crystalline activator, which is necessary in the state of the art, can also be omitted completely.

The inventive method and the inventive device are especially suitable for aluminizing turbine parts as well as HPT blades.

1-17. (canceled)

18. A method for CVD coating of workpieces, in particular for aluminizing, where a coating gas is used to coat the workpieces, comprising the steps of:
arranging the workpieces to be coated in a coating room;
arranging coating granules near the workpieces to be coated;
heating the coating room to a process temperature together with the workpieces to be coated and together with the coating granules; and
introducing a process gas onto the coating granules after reaching the process temperature to generate the coating gas.

19. The method according to claim 18, wherein the workpieces to be coated are positioned in several levels arranged one above the other in the coating room and wherein coating granules are arranged directly beneath the workpieces to be coated in the area of each level.

20. The method according to claim 19, wherein the process gas is introduced onto the coating granules in the area of each level.

21. The method according to claim 18, wherein a coating of the workpieces is performed after introducing the process gas onto the coating granules and after generating the coating gas.

22. The method according to claim 18, wherein a halide gas is used as the process gas.

23. The method according to claim 18, further comprising the step of generating a vacuum in the coating room before introducing the process gas into the coating room.

24. The method according to claim 18, wherein process parameters are kept constant during a holding time and wherein the workpieces are coated during the holding time.

25. The method according to claim 24, further comprising the step of pulsing a process pressure during the holding time by lowering the process pressure by withdrawing the coating gas and then generating a second coating gas.

26. The method according to claim 25, wherein after lowering the process pressure, the process gas is again introduced onto the coating granules until the process pressure has been restored.

27. The method according to claim 25, wherein the pulsing of the process pressure is performed once or cyclically by withdrawing the coating gas and reintroducing the process gas onto the coating granules and further comprising the step of depositing an interior coating on a hollow body of the workpieces by the process pressure pulsing step.

28. A device for CVD coating, in particular for aluminizing, comprising:
a coating room in which at least one workpiece to be coated is situated; and
a device for generating a coating gas which coats the workpiece;
wherein the device for generating the coating gas is arranged within the coating room near the workpiece to be coated.

29. The device according to claim 28, wherein the device for generating the coating gas includes multiple receptacle devices containing coating granules, wherein the multiple receptacle devices are arranged in levels running one above the other, and further wherein workpieces that are to be coated are positioned directly above and in the area of the receptacle devices filled with the coating granules.

30. The device according to claim 29, wherein the receptacle devices include a holding tray for the coating granules and a grating which borders the holding tray toward a top of the holding tray and wherein a workpiece to be coated is positioned on the grating.

31. The device according to claim 29, further comprising a a device for introducing a process gas arranged in an area of each receptacle device.

32. The device according to claim 31, wherein the device for introducing the process gas is designed as a branch of a vertically extending pipe in the coating room and wherein the branch protrudes into a corresponding receptacle device.

33. The device according to claim 28, further comprising a heating device for heating the coating room and the workpiece that is to be coated to a process temperature.

34. The device according to claim 28, further comprising a pump mechanism for generating a vacuum in the coating room and/or for pulsing a process pressure.
